(19) United States
(12) Patent Application Publication
(10) Pub. No.: US 2026/0171645 A1
(43) Pub. Date: Jun. 18, 2026

(54) COUPLED INDUCTORS UTILIZING INTERLACED SPIRALS FOR POWER COMBINERS, POWER SPLITTERS, AND TRANSFORMERS

(71) Applicant: QUALCOMM Incorporated, San Diego, CA (US)

(72) Inventors: Hsiao-Tsung YEN, San Diego, CA (US); Varish DIDDI, San Diego, CA (US); Francesco GATTA, San Diego, CA (US)

(21) Appl. No.: 18/984,681

(22) Filed: Dec. 17, 2024

(51) Int. Cl. H01P 5/12; H01F 27/28

(52) U.S. Cl. CPC H01P 5/12; H01F 27/28

(57) ABSTRACT

A transformer, power combiner, and power splitter, each including: a first primary winding comprising a first metal spiral formed at least in part from a first metal layer, wherein the first metal spiral extends in a first direction from a first end to a second end; and a secondary winding comprising a second metal spiral formed at least in part from the first metal layer, wherein the second metal spiral extends in the first direction from a third end to a fourth end, wherein first metal spiral is interlaced with the second metal spiral.

### FIELD

This disclosure relates to transformers, power combiners, and power splitters, and in particular to coupled inductors utilizing interlaced spirals for power combiners, power splitters, and transformers.

### BACKGROUND

Some power combiners and power splitters use transformers to effectuate signal power combining and signal power splitting, respectively. Accuracy in signal power combining and signal power splitting may be of interest. For example, if a power combiner is configured to equally combine the power of two input signals to generate an output signal, it may be desired for the output signal to have a power level being a sum of the power levels of the two input signals. Similarly, if a power splitter is configured to equally split the power of an input signal to generate a pair of output signals, it may be desired for each of the output signals to have a power level being half the power level of the input signal.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a power combiner. The power combiner includes: a first signal port configured to receive a first input signal; a second signal port configured to receive a second input signal; a third signal port configured to output an output signal with a power level related to a sum of a power level of the first input signal and a power level of the second input signal; a first transformer, including: a first primary winding including a first metal spiral formed at least in part from a first metal layer, wherein the first metal spiral extends in a counterclockwise direction from a first end coupled to the first signal port to a second end coupled directly or indirectly to a first signal ground; and a first secondary winding including a second metal spiral formed at least in part from the first metal layer, wherein the second metal spiral extends in the counterclockwise direction from a third end coupled to a second signal ground to a fourth end coupled directly or indirectly to the third signal port, wherein the first metal spiral is interlaced with the second metal spiral; and a second transformer, including: a second primary winding including a third metal spiral formed at least in part from the first metal layer, wherein the third metal spiral extends in a clockwise direction from a fifth end coupled to the second signal port to a sixth end coupled directly or indirectly to the first signal ground; and a second secondary winding including a fourth metal spiral formed at least in part from the first metal layer, wherein the fourth metal spiral extends in the clockwise direction from a seventh end coupled to the second signal ground to an eighth end coupled directly or indirectly to the third signal port, wherein the third metal spiral is interlaced with the fourth metal spiral.

Another aspect of the disclosure relates to a power splitter. The power splitter includes: a first signal port configured to receive an input signal; a second signal port configured to output a first output signal; a third signal port configured to output a second output signal, wherein a sum of respective power levels of the first and second output signals is related to a power level of the input signal; a first transformer, including: a first primary winding including a first metal spiral formed at least in part from a first metal layer, wherein the first metal spiral extends in a clockwise direction from a first end coupled to the first signal port to a second end coupled directly or indirectly to a first signal ground; and a first secondary winding including a second metal spiral formed at least in part from the first metal layer, wherein the second metal spiral extends in the clockwise direction from a third end coupled to a second signal ground to a fourth end coupled directly or indirectly to the second signal port, wherein the first metal spiral is interlaced with the second metal spiral; and a second transformer, including: a second primary winding including a third metal spiral formed at least in part from the first metal layer, wherein the third metal spiral extends in a counterclockwise direction from a fifth end coupled to the first signal port to a sixth end coupled to the second signal ground; and a second secondary winding including a fourth metal spiral formed at least in part from the first metal layer, wherein the fourth metal spiral extends in the counterclockwise direction from a seventh end coupled to a third signal ground to an eighth end coupled to the third signal port, wherein the third metal spiral is interlaced with the fourth metal spiral.

Another aspect of the disclosure relates to a transformer. The transformer includes a first primary winding including a first metal spiral formed at least in part from a first metal layer, wherein the first metal spiral extends in a first direction from a first end to a second end; and a secondary winding including a second metal spiral formed at least in part from the first metal layer, wherein the second metal spiral extends in the first direction from a third end to a fourth end, wherein first metal spiral is interlaced with the second metal spiral.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example wireless communication system in accordance with an aspect of the disclosure.

FIG. 2 illustrates a block diagram of the example transceiver in accordance with another aspect of the disclosure.

FIG. 3 illustrates a schematic diagram of an example power combiner in accordance with another aspect of the disclosure.

FIG. 4 illustrates top multilayer and cross-sectional views of an example power combiner in accordance with another aspect of the disclosure.

FIG. 5 illustrates top multilayer and cross-sectional views of another example power combiner in accordance with another aspect of the disclosure.

FIG. 6A illustrates a schematic diagram of an example transformer-based circuit in accordance with another aspect of the disclosure.

FIG. 6B illustrates top multilayer and cross-sectional views of an example transformer in accordance with another aspect of the disclosure.

FIG. 6C illustrates a schematic diagram of an example transformer-based circuit in accordance with another aspect of the disclosure.

FIG. 6D illustrates top multilayer and cross-sectional views of an example transformer in accordance with another aspect of the disclosure.

FIG. 7 illustrates a block diagram of an example receiver in accordance with another aspect of the disclosure.

FIG. 8 illustrates a schematic diagram of an example power splitter in accordance with another aspect of the disclosure.

FIG. 9 illustrates top multilayer and cross-sectional views of an example power combiner in accordance with another aspect of the disclosure.

FIG. 10 illustrates top multilayer and cross-sectional views of another example power combiner in accordance with another aspect of the disclosure.

FIG. 11 illustrates a block diagram of an example transformer in accordance with another aspect of the disclosure.

FIG. 12 illustrates a flow diagram of an example method of coupling signals across coupled inductors in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

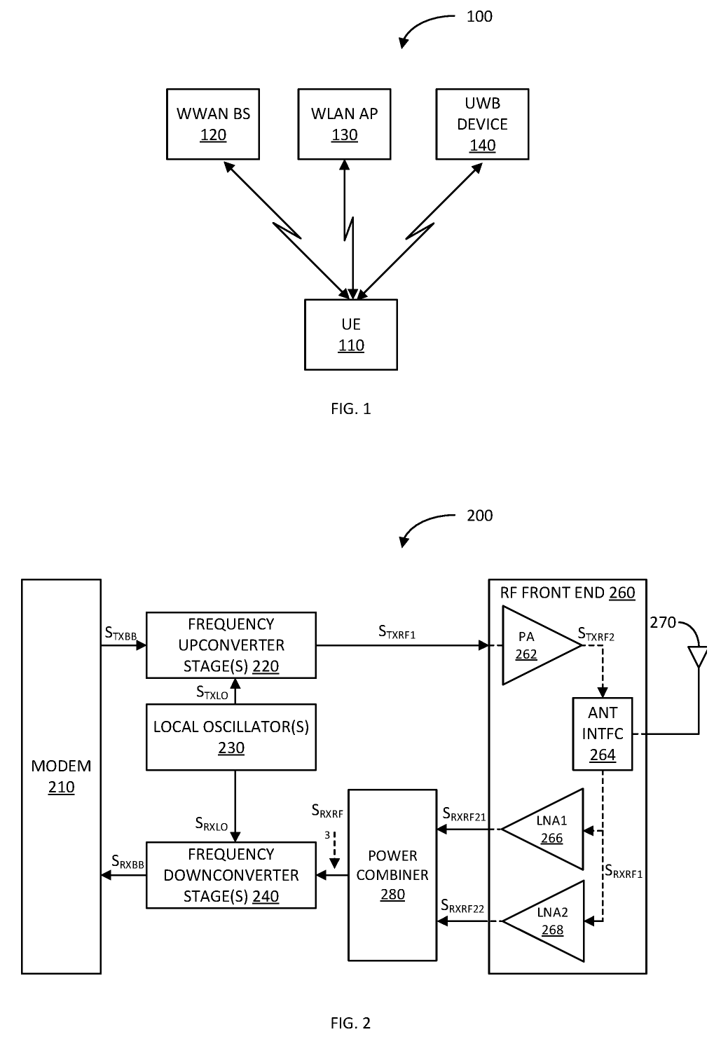

FIG. 1 illustrates a block diagram of an example wireless communication system 100 in accordance with another aspect of the disclosure. The wireless communication system 100 includes a user equipment (UE) 110, a wireless wide area network (WWAN) base station (BS) 120, a wireless local area network (WLAN) access point (AP)130, and a second ultra wideband (UWB) device 140. The UE 110 may include a transceiver for wirelessly communicating with the WWAN BS 120, WLAN AP 130, and/or UWB device 140 in accordance with different protocols (e.g., Fifth Generation (5G) or Sixth Generation (6G), New Radio (NR) protocol for WWAN communication, WiFi for WLAN communication, and UWB protocol for vehicle keyless access). Each of the protocols may facilitate wireless communication using different communication frequency bands.

FIG. 2 illustrates a block diagram of an example transceiver 200 in accordance with another aspect of the disclosure. The transceiver 200 may be implemented in the UE 110 for wirelessly communicating with any of the WWAN BS 120, WLAN AP 130, UWB device 140, and/or other.

The transceiver 200 includes a modem 210, one or more frequency upconverting stage(s) 220, one or more local oscillators 230, one or more frequency downconverting stage(s) 240, a power combiner 280, a radio frequency (RF) front end 260, and an antenna 270 (e.g., an antenna array). The RF front end 260, in turn, includes a power amplifier (PA) 262, an antenna interface 264 (e.g., duplexer, diplexer, or other type of antenna interface), a first low noise amplifier (LNA1) 266, and a second LNA2 268.

With regard to signal transmission, the modem 210 is configured to generate a transmit baseband signal S_{TXBB}. The one or more frequency upconverting stage(s) 220 is configured to frequency upconvert the transmit baseband signal S_{TXBB} (e.g., from baseband (BB) to radio frequency (RF) directly or via one or more intermediate frequencies (IFs)) using one or more transmit local oscillator signal(s) S_{TXLO} generated by the one or more local oscillators 230 to generate a first-stage transmit RF signal S_{TXRF1}. The PA 262 is configured to amplify the first-stage transmit RF signal S_{TXRF1} to generate a second-stage or output transmit RF signal S_{TXRF2}. The output RF signal S_{TXRF2} is provided to the antenna 270 via the antenna interface 264. The antenna 270 is configured to wirelessly radiate the output RF signal S_{TXRF2} for transmission to a remote device, such as one or more of the WWAN BS 120, WLAN AP 130, or UWB device 140.

With regard to signal reception, the antenna 270 may wirelessly sense/pickup a received RF signal S_{RXRF1} from a remote device, such as one or more of the WWAN BS 120, WLAN AP 130, or UWB device 140. The first LNA1 266 and the second LNA2 268 are configured to receive the RF signal S_{RXRF1} via the antenna interface 264. The first LNA1 266 is configured to amplify the received RF signal S_{RXRF1} to generate a first amplified received RF signal S_{RXRF21}. The second LNA2 268 is configured to amplify the received RF signal S_{RXRF1} to generate a second amplified received RF signal S_{RXRF22}. The power combiner 280 is configured to power combine the first and second amplified received RF signals S_{RXRF21} and S_{RXRF22} to generate a power-combined received RF signal S_{RXRF3}. That is, the power-combined received RF signal S_{RXRF3} has a power level being related to a sum of a power level of the first amplified RF signal S_{RXRF1} and a power level of the second amplified received RF signal S_{RXRF2}.

The one or more frequency downconverting stage(s) 240 is configured to frequency downconvert the power-combined received RF signal S_{RXRF3} (e.g., from RF to BB directly or via one or more IFs) using one or more received local oscillator signals S_{RXLO} generated by the one or more local oscillators 230 to generate a received BB signal S_{RXBB}. The modem 210 may receive and process the BB signal S_{RXBB} to extract and/or recover information or data therein.

The components of the transceiver 200 may be implemented as separate components or integrated into one or more integrated circuits (ICs) in various different manners. For example, the modem 210 may be integrated with the frequency converting components 220, 230, and 240, and the power combiner 280 into a single IC separate from the RF front end 260.

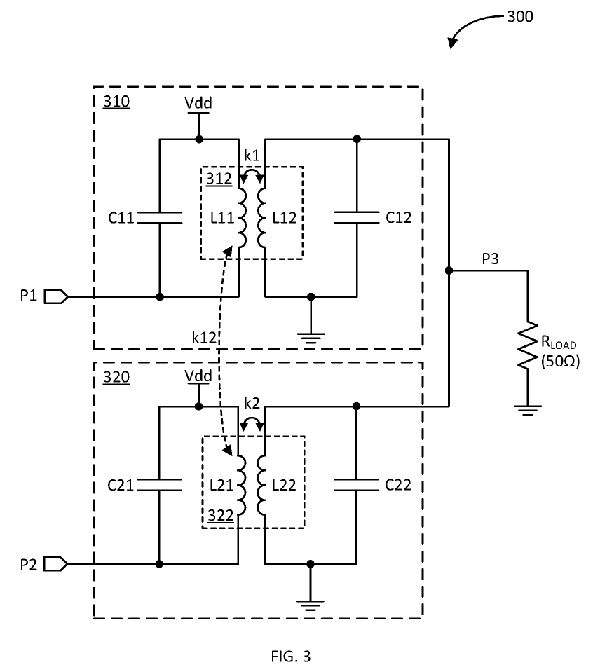

FIG. 3 illustrates a schematic diagram of an example power combiner 300 in accordance with another aspect of the disclosure. The power combiner 300 may be an example implementation of the power combiner 280 of transceiver 200. The power combiner 300 includes a first signal processing circuit 310 and a second signal processing circuit 320.

The first signal processing circuit 310 includes a first signal port P1 configured to receive a first input signal, such as the first amplified received RF signal S_{RXRF}₂₁ of transceiver 200. The first signal processing circuit 310 includes a first transformer 312 including a first primary winding (or inductor) L11 and a first secondary winding (or inductor) L12. The first primary and secondary windings L11 and L12 may have a mutual coupling factor of k1. The first primary winding L11 may be coupled between an optional upper voltage rail Vdd and the first signal port P1. Additionally, the first signal processing circuit 310 includes a first input capacitor C11 coupled in parallel with the first primary winding L11 between the upper voltage rail Vdd and the first signal port P1.

The upper voltage rail Vdd may provide a supply voltage to a first amplifier (e.g., the first LNA2 266 of transceiver 200) configured to generate the first input signal at the first signal port P1. The upper voltage rail Vdd is at an alternating current (AC) or signal ground (e.g., by coupling the upper voltage rail Vdd to ground via one or more parallel capacitors with an impedance of substantially zero Ohm (0Ω) with regard to the first input signal). If the upper voltage rail Vdd is not utilized, the end of the first primary winding L11 opposite the first signal port P1 may be coupled to signal ground. Signal ground, as used herein, covers both actual ground or grounding via one or more parallel capacitors with an impedance of substantially 0Ω with regard to the signal at the opposite end of the corresponding winding.

The first secondary winding L12 may be coupled between a third signal port P3 and a lower voltage rail (e.g., ground). Additionally, the first signal processing circuit 310 includes a first output capacitor C12 coupled in parallel with the first secondary winding L12 between the third signal port P3 and a lower voltage rail (e.g., signal ground). The third signal port P3 serves as an output port for the power combiner 300, as discussed further herein. The lower voltage rail may be coupled to AC (signal) ground and/or direct current (DC) ground.

The second signal processing circuit 320 includes a second signal port P2 configured to receive a second input signal, such as the second amplified received RF signal S_{RXRF22} of transceiver 200. The second signal processing circuit 320 includes a second transformer 322 including a second primary winding (or inductor) L21 and a second secondary winding (or inductor) L22. The second primary and secondary windings L21 and L22 may have a second mutual coupling factor of k2. The second primary winding L21 may be coupled between the optional upper voltage rail Vdd and the second signal port P2. Additionally, the second signal processing circuit 310 includes a second input capacitor C21 coupled in parallel with the second primary winding L21 between the upper voltage rail Vdd and the second signal port P2.

The upper voltage rail Vdd may provide a supply voltage to a second amplifier (e.g., the second LNA2 268 of transceiver 200) configured to generate the second input signal at the second signal port P2. As discussed, the upper voltage rail Vdd is at AC or signal ground (e.g., by coupling the upper voltage rail Vdd to ground via one or more parallel capacitors with an impedance of substantially 0Ω). If the upper voltage rail Vdd is not utilized, the end of the primary winding L21 opposite the second signal port P2 may be coupled to signal ground (e.g., by coupling that node to ground via one or more parallel capacitors with an impedance of substantially 0Ω).

The second secondary winding L22 may be coupled between the third signal port P3 and the lower voltage rail (e.g., signal ground). Additionally, the second signal processing circuit 320 includes a second output capacitor C22 coupled in parallel with the second secondary winding L22 between the third signal port P3 and the lower voltage rail. The lower voltage rail may be coupled to signal ground.

The third signal port P3 may be configured to generate an output signal with a power level related to a sum of the power level of the first input signal at the first signal port P1 and the power level of the second input signal at the second signal port P2. The output signal may correspond to the power-combined received RF signal S_{RXRF3} of transceiver 200. The third (output) signal port P3 may be coupled to a load R_{LOAD} (e.g., 50 Ohm (Ω) load), which may correspond to the one or more frequency downconverting stage(s) 240 of transceiver 200.

For the power combiner 300 to operate well to accurately power combine the first and second input signals to generate the output signal, the mutual couplings k1 and k2 associated with the first and second transformers 312 and 322 should be as high as possible. Additionally, a mutual coupling k12 may exist between the first and second primary windings L11 and L21. Also, for the power combiner 300 to operate well to accurately power combine the first and second input signals to generate the output signal, the mutual coupling k12 between the first and second primary windings L11 and L21 should be as low as possible.

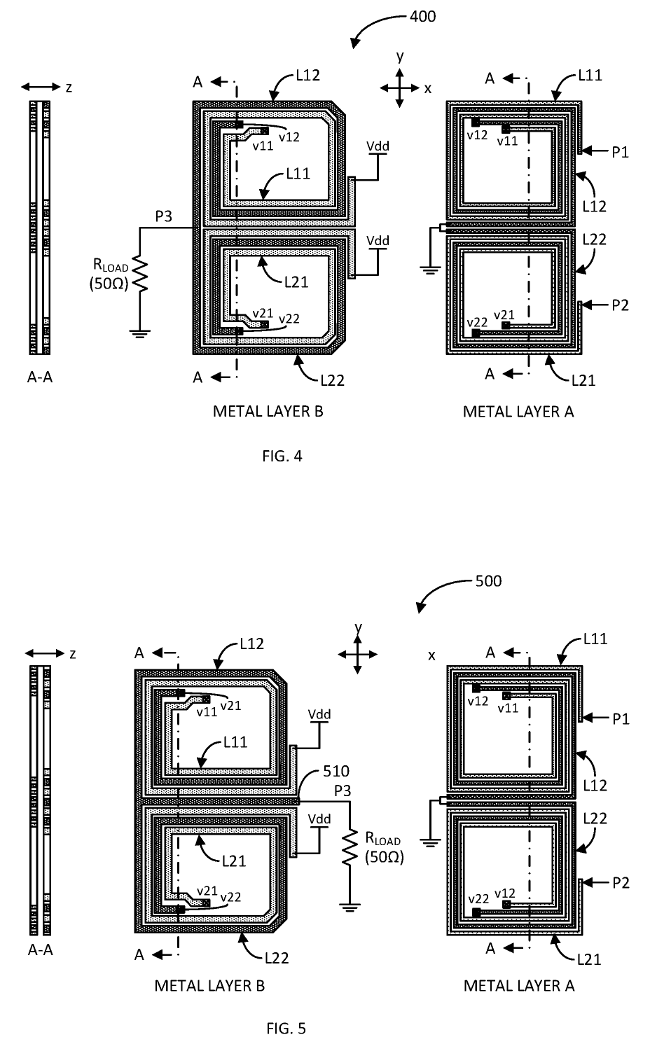

FIG. 4 illustrates top multilayer and cross-sectional views of an example power combiner 400 in accordance with another aspect of the disclosure. The power combiner 400 may be an example implementation of the power combiner 300. The power combiner 400 may be formed at least in part from one or more metal layers of an integrated circuit (IC), such as metal layer “A” and metal layer “B”.

The power combiner 400 includes a first primary winding (or inductor) L11 implemented as one or more metal spirals formed at least in part from one or more metal layers, respectively. For example, the first primary winding L11 includes a first metal spiral (represented by a light shading) formed at least in part from metal layer A. In this example, the first metal spiral (also referred to as L11) extends in a counterclockwise direction from a first end coupled to a first signal port P1 to a second end coupled to a first metallized via hole v11. Each metallized via hole described herein may include a set of metalized via holes to reduce the overall resistance of the coupling between metal layers.

The power combiner 400 further includes a first secondary winding (or inductor) L12 implemented as one or more metal spirals on one or more metal layers, respectively. For example, the first secondary winding L12 includes a second metal spiral (represented by a dark shading) formed at least in part from metal layer A. In this example, the second metal spiral (also referred to as L12) extends in a counterclockwise direction from a first end coupled to a lower voltage rail (e.g., signal ground) to a second end coupled to a second metallized via hole v12. The first metal spiral L11 is interlaced with the second metal spiral L12. That is, one or more sections of the first metal spiral L11 is situated between two or more sections of the second metal spiral L12 and/or one or more sections of the second metal spiral L12 is situated between two or more sections of the first metal spiral L11, respectively.

The power combiner 400 further includes a second primary winding (or inductor) L21 implemented as one or more metal spirals on one or more metal layers, respectively. For example, the second primary winding L21 includes a third metal spiral (represented by a light shading) formed at least in part from metal layer A. In this example, the third metal spiral (also referred to as L21) extends in a clockwise direction from a first end coupled to a second signal port P2 to a second end coupled to a third metallized via hole v21.

The power combiner 400 further includes a second secondary winding (or inductor) L22 implemented as one or more metal spirals on one or more metal layers. For example, the second secondary winding L22 includes a fourth metal spiral (represented by a dark shading) on metal layer A. In this example, the fourth metal spiral L22 extends in a clockwise direction from a first end coupled to the lower voltage rail (e.g., signal ground) to a second end coupled to a fourth metallized via hole v22. The third metal spiral L21 is interlaced with the fourth metal spiral L22. That is, one or more sections of the third metal spiral L21 is situated between two or more sections of the fourth metal spiral L22 and/or one or more sections of the fourth metal spiral L22 is situated between two or more sections of the third metal spiral L21, respectively.

The first metal spiral L11 may be extended on metal layer B. That is, on metal layer B, the first metal spiral L11 extends in a counterclockwise direction from a first end coupled to the first metallized via hole v11 to a second end coupled to an upper voltage rail Vdd (or more generally, signal ground). The second metal spiral L12 may also be extended on metal layer B. That is, the second metal spiral L12 extends in a counterclockwise direction from a first end coupled to the second metallized via hole v12 to a second end coupled to the third signal port P3. Similarly, on metal layer B, the first metal spiral L11 is interlaced with the second metal spiral L12. That is, one or more sections of the first metal spiral L11 is situated between two or more sections of the second metal spiral L12 and/or one or more sections of the second metal spiral L12 is situated between two or more sections of the first metal spiral L11.

The third metal spiral L21 may also be extended on metal layer B. That is, on metal layer B, the third metal spiral L21 extends in a clockwise direction from a first end coupled to the third metallized via hole v21 to a second end coupled to the upper voltage rail Vdd (or more generally, signal ground). The fourth metal spiral L22 may also be extended on metal layer B. That is, the fourth metal spiral L22 extends in a clockwise direction from a first end coupled to the fourth metallized via hole v22 to a second end coupled to the third signal port P3. Similarly, on metal layer B, the third metal spiral L21 is interlaced with the fourth metal spiral L22. That is, one or more sections of the third metal spiral L21 is situated between two or more sections of the fourth metal spiral L22 and/or one or more sections of the fourth metal spiral L22 is situated between two or more sections of the third metal spiral L21.

Similarly, as discussed with reference to power combiner 300, a first input signal may be received at the first signal port P1 of the power combiner 300, a second input signal may be received the second signal port P2 of the power combiner 300, and an output signal may be generated at the third signal port P3 of the power combiner 400. The output signal may have a power level being related substantially to a sum of the power level of the first input signal and the power level of the second input signal. Also, as discussed, a load R_{LOAD} coupled between the third signal port P3 and the lower voltage rail (e.g., ground) may be configured to receive the output signal. To achieve such power summation, the length of the first spiral inductor L11 may be substantially the same as the length of the third spiral inductor L21; and the length of the second spiral inductor L12 may be substantially the same as the length of the fourth spiral inductor L22.

The power combiner 400 achieves a relatively high mutual coupling k1 between the first primary and secondary windings L11 and L12, a relatively high mutual coupling k2 between the second primary and secondary windings L21 and L22, and a relatively low mutual coupling between the first and second primary windings L11 and L21. The interlaced spirals L11/L12 and L21/L22 on both metal layers A and B provide a high intralayer (along the x-y axes) mutual couplings k1 and k2, respectively. Additionally, interlaced spirals L11/L12 and L21/L22 being substantially vertically aligned with each other on metal layers A and B further provide high interlayer (along the z-axis) mutual couplings k1 and k2, respectively. The interlaced spirals L11/L12 and L21/L22 being spiraled in opposite directions (e.g., counterclockwise and clockwise), as well as segments of the spiral inductors L12 and L22 separating the spiral inductor L11 from spiral inductor L21 produces a relatively low mutual coupling k12 between the first primary windings L11 and L21. The relatively low mutual coupling k12 allows the power combiner 400 to be implemented in a smaller circuit or IC area, thereby providing significant area savings.

As suggested, the transformer 400 may be implemented on a single metal layer. In such case, the respective second ends of the first, second, third, and fourth metal spirals may be coupled directly (not via other respective cascaded metal spirals) to the upper voltage rail Vdd (e.g., signal ground), the third signal port P3, the upper voltage rail Vdd (e.g., signal ground), and the third signal port P3, respectively. If the transformer 400 is implemented on two, the second ends of the first, second, third, and fourth metal spirals coupled to metallized via holes v11, v12, v21, and v22 may be indirectly coupled (via other respective cascaded metal spirals) to the upper voltage rail Vdd (e.g., signal ground), the third signal port P3, the upper voltage rail Vdd (e.g., signal ground), and the third signal port P3, respectively. Such direct and indirect concept may be extended to transformers implemented on more than two metal layers, as well as the other transformers described herein.

FIG. 5 illustrates top multilayer and cross-sectional views of another example power combiner 500 in accordance with another aspect of the disclosure. The power combiner 500 is a variation of power combiner 400 and includes many of the similar/same elements as indicated by the same reference labels. The power combiner 500 differs from power combiner 400 in that the power combiner 500 in that the secondary windings L12 and L22 includes a common metal segment 510 extending to the third signal port P3. The common metal segment 510 is situated between the primary windings L11 and L21 on metal layer B. The common metal segment 510 further reduces the mutual coupling k12 between the primary windings L11 and L21. The lower mutual coupling k12 allows the power combiner 500 to be implemented in a smaller circuit or IC area, thereby providing significant area savings.

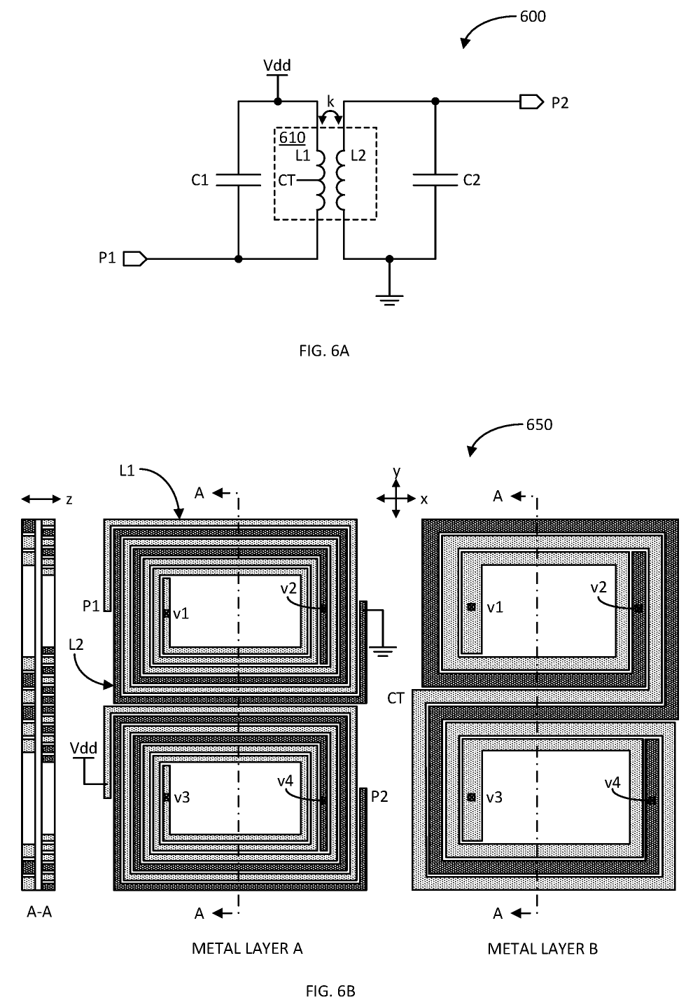

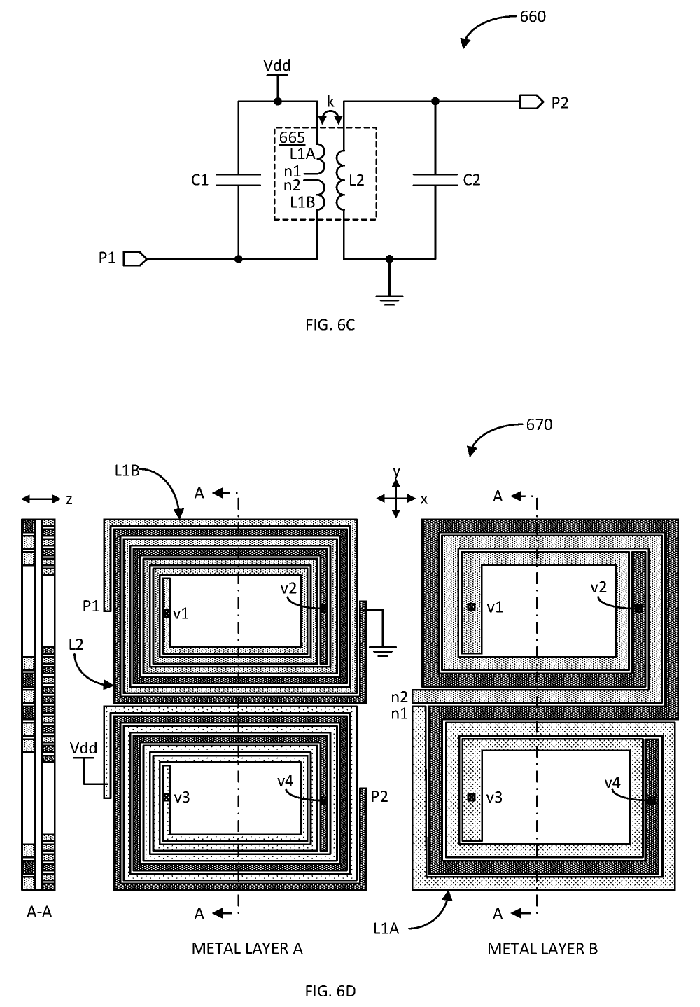

FIG. 6A illustrates a schematic diagram of an example transformer-based circuit 600 in accordance with another aspect of the disclosure. The transformer-based circuit 600 may be used in many applications, such as in power combiners, power splitters, baluns, and others.

The transformer-based circuit 600 includes a transformer 610 including a primary winding (or inductor) L1 electromagnetically coupled to a secondary winding (or inductor) L2 with a mutual coupling factor of k. The primary winding L1 is coupled between an optional upper voltage rail Vdd (or signal ground) and a first signal port P1. The first signal port P1 may be configured to receive an input signal (e.g., from an amplifier or other device). The optional upper voltage rail Vdd may provide a supply voltage to an amplifier or other device coupled to the first signal port P1. The transformer-based circuit 600 may include an input capacitor C1 coupled in parallel with the primary winding L1 between the upper voltage rail Vdd and the first signal port P1. The primary winding L1 may include a center tap (CT).

The secondary winding L2 may be coupled between a second signal port P2 and a lower voltage rail (e.g., ground or more generally signal ground). The second signal port P2 may be configured to provide an output signal to another device. The transformer-based circuit 600 may include an output capacitor C2 coupled in parallel with the secondary winding L2 between the second signal port P2 and the lower voltage rail.

FIG. 6B illustrates top multilayer and cross-sectional views of an example transformer 650 in accordance with another aspect of the disclosure. The transformer 650 may be an example implementation of the transformer 610 of transformer-based circuit 600. The transformer 650 may be implemented on one or more metal layers of an integrated circuit (IC), such as metal layer “A” and metal layer “B”.

The transformer 650 includes a primary winding (or inductor) L1 implemented as one or more metal spirals on the same and/or different metal layers. For example, the primary winding L1 includes a first metal spiral (represented by a light shading) formed at least in part from metal layer A. In this example, the first metal spiral (also referred to as L1) extends in a clockwise direction from a first end coupled to a first signal port P1 to a second end coupled to a first metallized via hole v1.

The transformer 650 further includes a secondary winding (or inductor) L2 implemented as one or more metal spirals on the same and/or different metal layers. For example, the secondary winding L2 includes a second metal spiral L2 (represented by a dark shading) formed at least in part from metal layer A. In this example, the second metal spiral L2 extends in a clockwise direction from a first end coupled to ground (or more generally, signal ground) to a second end coupled to a second metallized via hole v2. The first metal spiral L1 is interlaced with the second metal spiral L2. That is, one or more sections of the first metal spiral L1 is situated between two or more sections of the second metal spiral L2 and/or one or more sections of the second metal spiral L2 is situated between two or more sections of the first metal spiral L1, respectively.

The primary winding L1 may be extended on metal layer B. In this regard, the primary winding L1 includes a third metal spiral (also referred to as L1) extending in the clockwise direction from a first end coupled to the first metallized via hole v1 to a second end serving as a center tap (CT) of the primary winding L1. Similarly, the secondary winding L2 may be extended on metal layer B. In this regard, the secondary winding L2 includes a fourth metal spiral (also referred to as L2) extending in the clockwise direction from a first end coupled to the second metallized via hole v2 to a second end situated adjacent to the CT of the primary winding L1. The third metal spiral L1 is also interlaced with the fourth metal spiral L2. That is, one or more sections of the third metal spiral L1 is situated between two or more sections of the fourth metal spiral L2 and/or one or more sections of the fourth metal spiral L2 is situated between two or more sections of the third metal spiral L1, respectively.

The primary winding L1 may be further extended on metal layer B. In this regard, the primary winding L1 includes a fifth metal spiral (also referred to as L1) extending in a counterclockwise direction from a first end coupled to the CT to a second end coupled to a third metallized via hole v3. Similarly, the secondary winding L2 may be further extended on metal layer B. In this regard, the secondary winding L1 includes a sixth metal spiral (also referred to as L2) extending in the counterclockwise direction from a first end adjacent to the CT to a second end coupled to a fourth metallized via hole v4. The fifth metal spiral L1 is also interlaced with the sixth metal spiral L2. That is, one or more sections of the fifth metal spiral L1 is situated between two or more sections of the sixth metal spiral L2 and/or one or more sections of the sixth metal spiral L2 is situated between two or more sections of the fifth metal spiral L1, respectively.

The primary winding L1 may be further extended on metal layer A. In this regard, the primary winding L1 includes a seventh metal spiral (also referred to as L1) extending in the counterclockwise direction from a first end coupled to the third metallized via hole v3 to a second end coupled to upper voltage rail Vdd (or more generally, signal ground). Similarly, the secondary winding L2 may also be further extended on metal layer A. In this regard, the secondary winding L2 includes an eighth metal spiral (also referred to as L2) extending in the counterclockwise direction from a first end coupled to a fourth metallized via hole v4 to a second end coupled to a second signal port P2. The seventh metal spiral L1 is also interlaced with the eighth metal spiral L2. That is, one or more sections of the seventh metal spiral L1 is situated between two or more sections of the eighth metal spiral L2 and/or one or more sections of the eighth metal spiral L2 is situated between two or more sections of the seventh metal spiral L1, respectively.

The transformer 650 achieves a high mutual coupling k between the primary winding L1 and secondary winding L2. The interlaced spirals L1/L2 on the same metal layers A and B provide high intralayer (along the x-y axes) mutual coupling k, respectively. Additionally, the interlaced spirals L1/L2 on metal layers A and B are substantially vertically aligned to further provide high interlayer (along the z-axis) mutual coupling k.

The transformer 650 has an 8-shaped configuration. That is, the spirals of the primary winding L1 at the top section of the transformer 650 (e.g., from P1 to CT) extend in the clockwise direction, whereas the spirals of the primary winding L1 at the adjacent bottom section of the transformer (e.g., from CT to Vdd) extend in the counterclockwise direction. Thus, any current induced from other proximate devices are cancelled due to the opposite clockwise configurations of the primary winding L1 provided by the 8-shaped configuration. Thus, the 8-shaped configuration of the transformer 650 provides significant current induction isolation from other devices. Also, the spirals of the secondary winding L2 also form an 8-shaped configuration for current induction isolation from other devices.

FIG. 6C illustrates a schematic diagram of another example transformer-based circuit 660 in accordance with another aspect of the disclosure. The transformer-based circuit 660 is a variation of transformer-based circuit 600, and includes some of the same elements as indicated by the same reference labels. The transformer-based circuit 600 differs from transformer-based circuit 600 in that it includes a transformer 665 with separate primary windings L1A and L1B. The first primary winding L1A is coupled between the upper voltage rail Vdd (or more generally, signal ground) and a first node n1. The second primary winding L1B is coupled between a second node n2 and the first signal port P1. In this configuration, the transformer 665 or transformer-based circuit 660 may be used in many different applications.

FIG. 6D illustrates top multilayer and cross-sectional views of an example transformer 670 in accordance with another aspect of the disclosure. The transformer 670 may be an example implementation of the transformer 665 of transformer-based circuit 660. The transformer 670 may be a variation of transformer 650 with regard to splitting the primary winding L1 of transformer 650 into separate primary windings L1A and L1B.

In this regards, the primary winding L1B extends from the first signal port P1 in a clockwise direction to the first metallized via hole v1 on metal layer A. The primary winding L1B further extends from the first metallized via hole v1 clockwise to a second node n2 on metal layer B. The primary winding L1A extends from a first node n1 in a counterclockwise direction to the third metallized via hole v3 on metal layer B. The primary winding L1A further extends from the third metallized via hole v3 counterclockwise to an upper voltage rail Vdd (or more generally, signal ground).

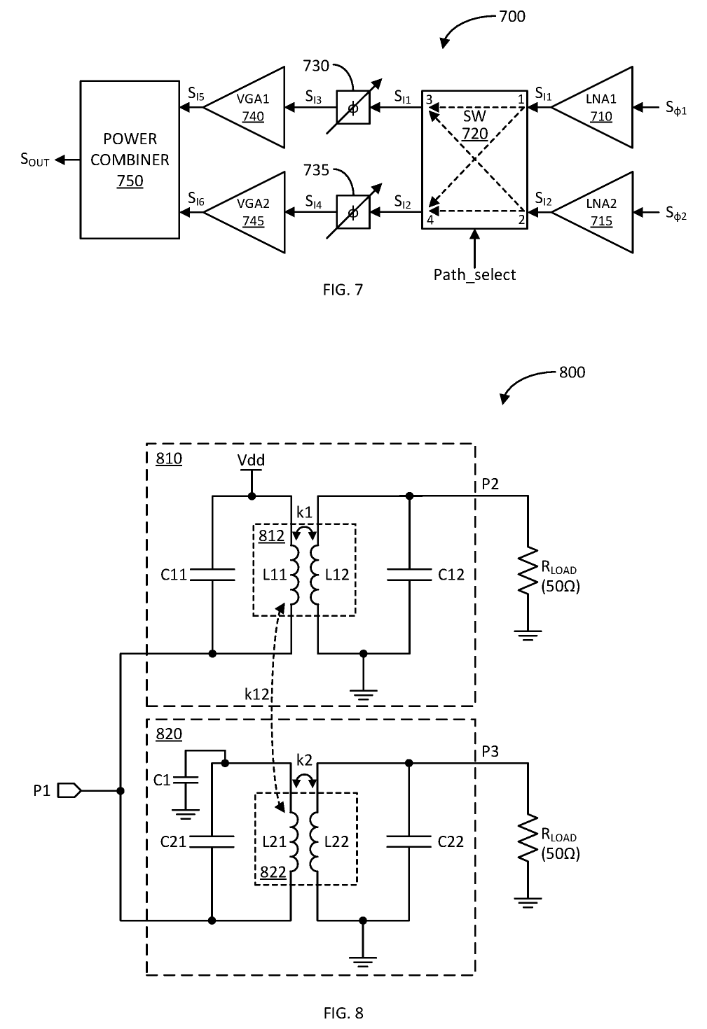

FIG. 7 illustrates a block diagram of an example receiver 700 in accordance with another aspect of the disclosure. The receiver 700 may be another example of where a power combiner may be employed. The receiver 700 includes a first low noise amplifier (LNA1) 710, a second LNA2 715, a switch matrix 720, a first phase shifter 730, a second phase shifter 735, a first variable gain amplifier (VGA1) 740, a second VGA2 745, and a power combiner 750.

The first LNA1 710 is configured to receive and amplify a first input signal S_{ϕ1} to generate a first intermediate signal S_{I1}. The second LNA2 715 is configured to receive and amplify a second input signal S_{ϕ2}to generate a first intermediate signal S_{I1}. The first and second input signals S_{ϕ1} and S_{ϕ2} may be the same signal but shifted with different phases ϕ1 and ϕ2, respectively.

The first LNA1 includes an output coupled to port 1 of the switch matrix 720. The second LNA2 includes an output coupled to port 2 of the switch matrix 720. The switch matrix 720 includes a port 3 coupled to an input of the first phase shifter 730. The switch matrix 720 also includes a port 4 coupled to an input of the second phase shifter 735. The switch matrix 720 includes a control input configured to receive a path_select control signal for selecting the signal paths for the first and second intermediate signals S_{I1} and S_{I2}. The path_select control signal may configure the switch matrix 720 to route the first intermediate signal S_{I1} from port 1 to port 3 and/or port 4, and route the second intermediate signal S_{I2} from port 1 to port 3 and/or port 4. In this example, the path_select control signal configures the switch matrix 720 to route the first intermediate signal S_{I1} from port 1 to port 3, and the second intermediate signal S_{I2} from port 2 to port 4.

The first phase shifter 730 is configured to phase shift the first intermediate signal S_{I1} to generate a third intermediate signal S_{I3}. The second phase shifter 735 is configured to phase shift the second intermediate signal S_{I}₂ to generate a third intermediate signal S_{I4}. The phase shifts of the first and second intermediate signals S_{I1} and S_{I}₂ may be effectuated so that the third and fourth intermediate signals S_{I3} and S_{I4} have substantially the same phase. This may be done for efficient power combining by the power combiner 750. The first VGA1 is configured to amplify the third intermediate signal S_{I3} to generate a fifth intermediate signal S_{I5}. The second VGA2 is configured to amplify the fourth intermediate signal S_{I4} to generate a sixth intermediate signal S_{I6}.

The power combiner 750 is configured to generate an output signal S_{OUT} with a power level being related to a sum of the power level of the fifth intermediate signal S_{I5} and the power level of the sixth intermediate signal S_{I6}. The power combiner 750 may be implemented in accordance with any of the power combiners 300, 400, and 500, or may employ any of the transformer-based circuits 600 and 660, or any of the transformers 610, 650, 665, and 670.

FIG. 8 illustrates a schematic diagram of an example power splitter 800 in accordance with another aspect of the disclosure. The power splitter 800 may be based on power combiner 300. The power splitter 800 includes a first signal processing circuit 810 and a second signal processing circuit 820.

The first signal processing circuit 810 is coupled to a first signal port P1 configured to receive an input signal. The first signal processing circuit 810 includes a first transformer 812 including a first primary winding (or inductor) L11 and a first secondary winding (or inductor) L12. The first primary and secondary windings L11 and L12 may have a mutual coupling factor of k1. The first primary winding L11 may be coupled between an upper voltage rail Vdd (or more generally, signal ground) and the first signal port P1. Additionally, the first signal processing circuit 810 may include a first input capacitor C11 coupled in parallel with the first primary winding L11 between the upper voltage rail Vdd and the first signal port P1. The upper voltage rail Vdd may provide a supply voltage to an amplifier configured to generate the input signal at the first signal port P1.

The first secondary winding L12 may be coupled between a second signal port P2 and a lower voltage rail (e.g., ground, or more generally, signal ground). Additionally, the first signal processing circuit 810 includes a first output capacitor C12 coupled in parallel with the first secondary winding L12 between the second signal port P2 and the lower voltage rail. Additionally, the first signal processing circuit 810 includes a first output capacitor C12 coupled in parallel with the first secondary winding L12 between the second signal port P2 and the lower voltage rail. The second signal port P2 serves as a first output port for the power splitter 800.

The second signal processing circuit 820 is also coupled to the first signal port P1 to receive the input signal. The second signal processing circuit 820 includes a second transformer 822 including a second primary winding (or inductor) L21 and a second secondary winding (or inductor) L22. The second primary and secondary windings L21 and L22 may have a second mutual coupling factor of k2. The second primary winding L21 may be coupled between signal ground (effectuated by capacitor C1 coupled to ground) and the first signal port P1. Additionally, the second signal processing circuit 820 includes a second input capacitor C21 coupled in parallel with the second primary winding L21 between the signal ground and the first signal port P1.

The second primary winding L22 may be coupled between a third signal port and the lower voltage rail (e.g., ground, or more generally, signal ground). Additionally, the second signal processing circuit 820 includes a second output capacitor C22 coupled in parallel with the second primary winding L22 between the third signal port P3 and the lower voltage rail. The third signal port P3 serves as a second output port for the power splitter 800.

The second and third signal ports P2 and P3 may be configured to generate an output signal each having a power level related to substantially half the power level of the input signal at the first signal port P1. A first load R_{LOAD1} (e.g., 50 Ohm (Ω) load) may be coupled between the second signal port P2 and the lower voltage rail (e.g., ground). A second load R_{LOAD2} (e.g., 50 Ohm (Ω) load) may be coupled between the third signal port P3 and the lower voltage rail (e.g., ground).

Similarly, for the power splitter 800 to operate well to substantially equally power split the input signal to generate the output signals, the mutual couplings k1 and k2 associated with the first and second transformers 812 and 822 should be as high as possible. Additionally, a mutual coupling k12 may exist between the first and second primary windings L11 and L21. Thus, for the power splitter 800 to operate well so as to substantially equally split the power of the input signal to generate the output signals, the mutual coupling k12 between the first and second primary windings L11 and L21 should be as low as possible. Accordingly, the power splitter 800 may be implemented similar to power combiners 400 and 500 as discussed further herein.

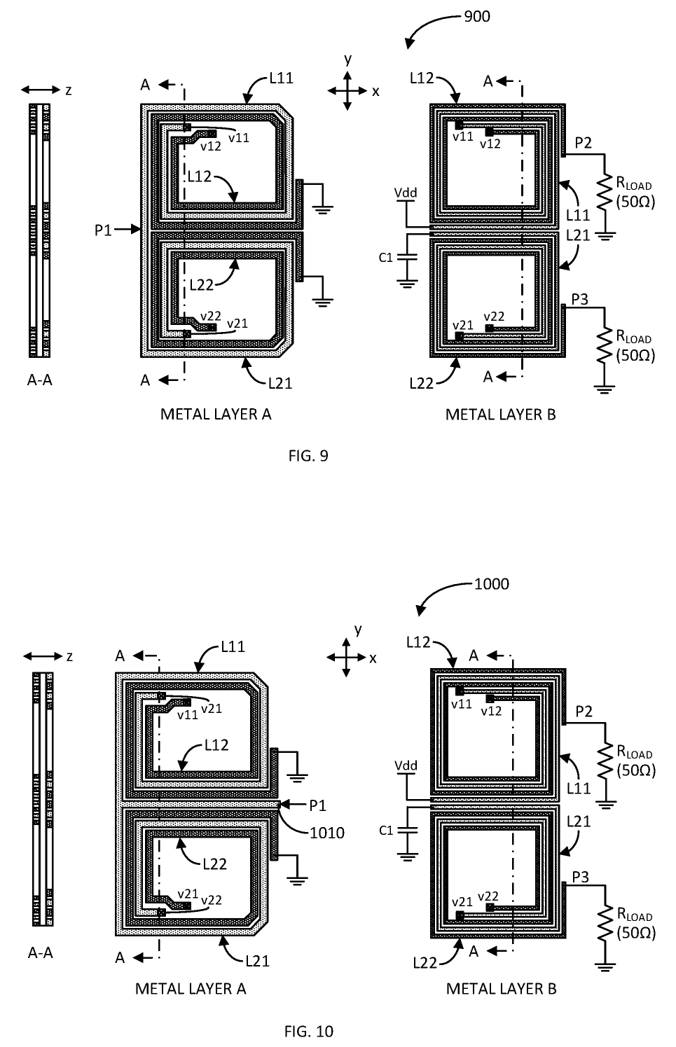

FIG. 9 illustrates top multilayer and cross-sectional views of an example power splitter 900 in accordance with another aspect of the disclosure. The power splitter 900 may be an example implementation of the power splitter 800. The power splitter 900 may be implemented on one or more metal layers of an integrated circuit (IC), such as metal layer “A” and metal layer “B”.

The power splitter 900 includes a first primary winding (or inductor) L11 implemented as one or more metal spirals on one or more metal layers, respectively. For example, the first primary winding L11 includes a first metal spiral (represented by a light shading) on metal layer A. In this example, the first metal spiral (also referred to as L11) extends in a clockwise direction from a first end coupled to a first signal port P1 to a second end coupled to a first metallized via hole v11.

The power splitter 900 further includes a first secondary winding (or inductor) L12 implemented as one or more metal spirals on one or more metal layers, respectively. For example, the first secondary winding L12 includes a second metal spiral (represented by a dark shading) on metal layer A. In this example, the second metal spiral (also referred to as L12) extends in a clockwise direction from a first end coupled to a lower voltage rail (e.g., signal ground) to a second end coupled to a second metallized via hole v12. The first metal spiral L11 is interlaced with the second metal spiral L12. That is, one or more sections of the first metal spiral L11 is situated between two or more sections of the second metal spiral L12 and/or one or more sections of the second metal spiral L12 is situated between two or more sections of the first metal spiral L11, respectively.

The power splitter 900 further includes a second primary winding (or inductor) L21 implemented as one or more metal spirals on one or more metal layers, respectively. For example, the second primary winding L21 includes a third metal spiral (represented by a light shading) formed at least in part from metal layer A. In this example, the third metal spiral (also referred to as L21) extends in a counterclockwise direction from a first end coupled to the first signal port P1 to a second end coupled to a third metallized via hole v21.

The power splitter 900 further includes a second secondary winding (or inductor) L22 implemented as one or more metal spirals on one or more metal layers. For example, the second secondary winding L22 includes a fourth metal spiral (represented by a dark shading) formed at least in part from metal layer A. In this example, the fourth metal spiral L22 extends in a counterclockwise direction from a first end coupled to the lower voltage rail (e.g., signal ground) to a second end coupled to a fourth metallized via hole v22. The third metal spiral L21 is interlaced with the fourth metal spiral L22. That is, one or more sections of the third metal spiral L21 is situated between two or more sections of the fourth metal spiral L22 and/or one or more sections of the fourth metal spiral L22 is situated between two or more sections of the third metal spiral L21, respectively.

The first metal spiral L11 may be extended formed at least in part from metal layer B. That is, on metal layer B, the first metal spiral L11 extends in a clockwise direction from a first end coupled to the first metallized via hole v11 to a second end coupled to an upper voltage rail Vdd (or more generally, signal ground). The second metal spiral L12 may also be extended on metal layer B. That is, the second metal spiral L12 extends in a clockwise direction from a first end coupled to the second metallized via hole v12 to a second end coupled to a second signal port P2. Similarly, on metal layer B, the first metal spiral L11 is interlaced with the second metal spiral L12. That is, one or more sections of the first metal spiral L11 is situated between two or more sections of the second metal spiral L12 and/or one or more sections of the second metal spiral L12 is situated between two or more sections of the first metal spiral L11.

The third metal spiral L21 may also be extended on metal layer B. That is, on metal layer B, the third metal spiral L21 extends in a counterclockwise direction from a first end coupled to the third metallized via hole v21 to a second end coupled to signal ground via capacitor C1 coupled between the second end of the third metal spiral and ground. The fourth metal spiral L22 may also be extended on metal layer B. That is, the fourth metal spiral L22 extends in a counterclockwise direction from a first end coupled to the fourth metallized via hole v22 to a second end coupled to a third signal port P3. Similarly, on metal layer B, the third metal spiral L21 is interlaced with the fourth metal spiral L22. That is, one or more sections of the third metal spiral L21 is situated between two or more sections of the fourth metal spiral L22 and/or one or more sections of the fourth metal spiral L22 is situated between two or more sections of the third metal spiral L21.

Similarly, as discussed with reference to power splitter 800, an input signal may be received at the first signal port P1 of the power splitter 900, a first output signal may be generated at the second signal port P2 of the power splitter 900, and a second output signal may be generated at the third signal port P3 of the power splitter 900. The first and second output signals may each have a power level related to substantially half the power level of the input signal. Also, as discussed, a first load R_{LOAD} coupled between the second signal port P2 and the lower voltage rail (e.g., ground) may be configured to receive the first output signal; and a second load R_{LOAD} coupled between the third signal port P3 and the lower voltage rail (e.g., ground) may be configured to receive the second output signal. To achieve such power splitting, the length of the first spiral inductor L11 may be substantially the same as the length of the third spiral inductor L21; and the length of the second spiral inductor L12 may be substantially the same as the length of the fourth spiral inductor L22.

The power splitter 900 achieves a relatively high mutual coupling k1 between the first primary and secondary windings L11 and L12, a relatively high mutual coupling k2 between the second primary and secondary windings L21 and L22, and a relatively low mutual coupling between the first and second primary windings L11 and L21. The interlaced spirals L11/L12 and L21/L22 on both metal layers A and B provide a high intralayer (along the x-y axes) mutual couplings k1 and k2, respectively. Additionally, interlaced spirals L11/L12 and L21/L22 being substantially vertically aligned with each other on metal layers A and B further provide high interlayer (along the z-axis) mutual couplings k1 and k2, respectively. The interlaced spirals L11/L12 and L21/L22 being spiraled in opposite directions (e.g., clockwise and counterclockwise), as well as segments of the spiral inductors L12 and L22 separating the spiral inductor L11 from spiral inductor L21 produces a relatively low mutual coupling k12 between the first primary windings L11 and L21. The low mutual coupling k12 allows the power splitter 900 to be implemented in a smaller circuit or IC area, thereby providing significant area savings.

FIG. 10 illustrates top multilayer and cross-sectional views of another example power splitter 1000 in accordance with another aspect of the disclosure. The power splitter 1000 is a variation of power splitter 900 and includes many of the similar/same elements as indicated by the same reference labels. The power splitter 1000 differs from power splitter 900 in that the power splitter 1000 in that the primary windings L11 and L21 includes a common metal segment 1010 on metal layer A extending from the first signal port P3. The common metal segment 1010 is situated between the secondary windings L12 and L22. The common metal segment 1010 further reduces the mutual coupling k12 between the secondary windings L12 and L22.

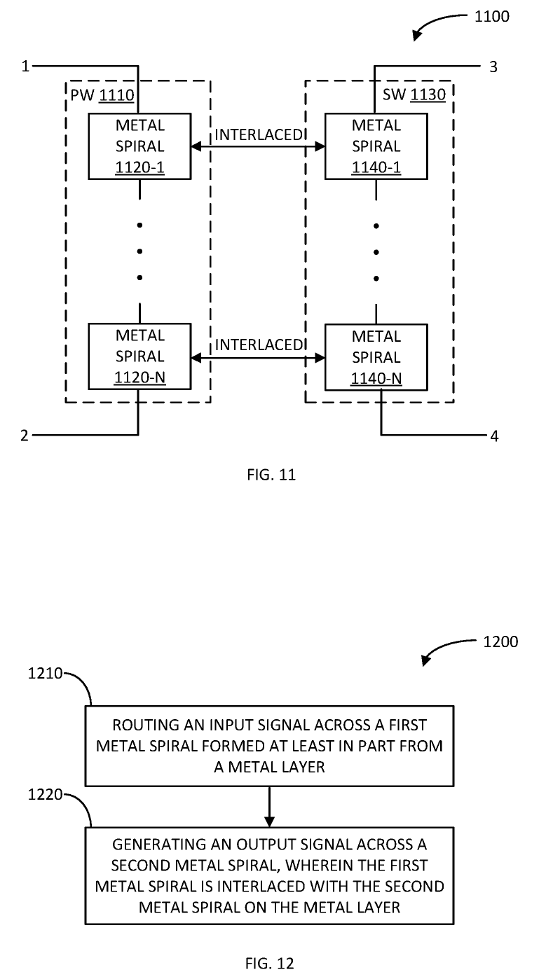

FIG. 11 illustrates a block diagram of an example transformer 1100 in accordance with another aspect of the disclosure. The transformer 1100 includes a primary winding (PW) 1110 including a first set of one or more cascaded metal spirals 1120-1 to 1120-N coupled between a first port (1) and a second port (2), where N is an integer of one or more. The transformer 1100 further includes a secondary winding (SW) 1130 including a second set of one or more cascaded metal spirals 1140-1 to 1140-N coupled between a third port (3) and a fourth port (4). The first set of one or more cascaded metal spirals 1120-1 to 1120-N are interlaced with the second set of one or more cascaded metal spirals 1140-1 to 1140-N, respectively.

FIG. 12 illustrates a flow diagram of an example method 1200 of coupling signals across coupled inductors in accordance with another aspect of the disclosure. The method 1200 includes routing an input signal via a first metal spiral formed at least in part from a metal layer (block 1210). Examples of means for routing an input signal across a first metal spiral formed at least in part from a metal layer include any of the primary windings described herein. The method 1200 further includes generating an output signal across a second metal spiral, wherein the first metal spiral is interlaced with the second metal spiral on the metal layer (block 1220). Examples of means for generating an output signal across a second metal spiral, wherein the first metal spiral is interlaced with the second metal spiral on the metal layer, include any of the secondary windings described herein.

The following provides an overview of aspects of the present disclosure:

Aspect 1: A power combiner, comprising: a first signal port configured to receive a first input signal; a second signal port configured to receive a second input signal; a third signal port configured to output an output signal with a power level related to a sum of a power level of the first input signal and a power level of the second input signal; a first transformer, comprising: a first primary winding comprising a first metal spiral formed at least in part from a first metal layer, wherein the first metal spiral extends in a counterclockwise direction from a first end coupled to the first signal port to a second end coupled directly or indirectly to a first signal ground; and a first secondary winding comprising a second metal spiral formed at least in part from the first metal layer, wherein the second metal spiral extends in the counterclockwise direction from a third end coupled to a second signal ground to a fourth end coupled directly or indirectly to the third signal port, wherein the first metal spiral is interlaced with the second metal spiral; and a second transformer, comprising: a second primary winding comprising a third metal spiral formed at least in part from the first metal layer, wherein the third metal spiral extends in a clockwise direction from a fifth end coupled to the second signal port to a sixth end coupled directly or indirectly to the first signal ground; and a second secondary winding comprising a fourth metal spiral formed at least in part from the first metal layer, wherein the fourth metal spiral extends in the clockwise direction from a seventh end coupled to the second signal ground to an eighth end coupled directly or indirectly to the third signal port, wherein the third metal spiral is interlaced with the fourth metal spiral.

Aspect 2: The power combiner of aspect 1, wherein at least one of the second metal spiral or the fourth metal spiral each includes a segment separating the first metal spiral from the third metal spiral.

Aspect 3: The power combiner of aspect 1 or 2, wherein: the first primary winding further comprises a fifth metal spiral formed at least in part from a second metal layer, wherein the fifth metal spiral extends in the counterclockwise direction from a ninth end coupled to the second end of the first metal spiral via a first metallized via hole to a tenth end coupled to the first signal ground; the first secondary winding further comprises a sixth metal spiral formed at least in part from the second metal layer, wherein the sixth metal spiral extends in the counterclockwise direction from an eleventh end coupled to the fourth end of the second metal spiral via a second metallized via hole to a twelfth end coupled to the third signal port, wherein the fifth metal spiral is interlaced with the sixth metal spiral; the second primary winding further comprises a seventh metal spiral formed at least in part from the second metal layer, wherein the seventh metal spiral extends in the clockwise direction from a thirteenth end coupled to the sixth end of the third metal spiral via a third metallized via hole to a fourteenth end coupled to the first signal ground; and the second secondary winding further comprises an eighth metal spiral formed at least in part from the second metal layer, wherein the eighth metal spiral extends in the clockwise direction from a fifteenth end coupled to the eighth end of the fourth metal spiral via a fourth metallized via hole to a sixteenth end coupled to the third signal port, wherein the seventh metal spiral is interlaced with the eighth metal spiral.

Aspect 4: The power combiner of aspect 3, wherein the sixth metal spiral and the eighth metal spiral include a common metal segment separating the fifth metal spiral from the seventh metal spiral.

Aspect 5: The power combiner of any one of aspects 1-4, wherein: the first signal ground comprises an upper voltage rail; and the second signal ground comprises a lower voltage rail.

Aspect 6: A power splitter, comprising: a first signal port configured to receive an input signal; a second signal port configured to output a first output signal; a third signal port configured to output a second output signal, wherein a sum of respective power levels of the first and second output signals is related to a power level of the input signal; a first transformer, comprising: a first primary winding comprising a first metal spiral formed at least in part from a first metal layer, wherein the first metal spiral extends in a clockwise direction from a first end coupled to the first signal port to a second end coupled directly or indirectly to a first signal ground; and a first secondary winding comprising a second metal spiral formed at least in part from the first metal layer, wherein the second metal spiral extends in the clockwise direction from a third end coupled to a second signal ground to a fourth end coupled directly or indirectly to the second signal port, wherein the first metal spiral is interlaced with the second metal spiral; and a second transformer, comprising: a second primary winding comprising a third metal spiral formed at least in part from the first metal layer, wherein the third metal spiral extends in a counterclockwise direction from a fifth end coupled to the first signal port to a sixth end coupled to a third signal ground; and a second secondary winding comprising a fourth metal spiral formed at least in part from the first metal layer, wherein the fourth metal spiral extends in the counterclockwise direction from a seventh end coupled to the second signal ground to an eighth end coupled to the third signal port, wherein the third metal spiral is interlaced with the fourth metal spiral.

Aspect 7: The power splitter of aspect 6, wherein at least one of the second metal spiral or the fourth metal spiral each includes a metal segment separating the first metal spiral from the third metal spiral.

Aspect 8: The power splitter of aspect 6 or 7, wherein: the first primary winding further comprises a fifth metal spiral formed at least in part from a second metal layer, wherein the fifth metal spiral extends in the clockwise direction from a ninth end coupled to the second end of the first metal spiral via a first metallized via hole to a tenth end coupled to the first signal ground; the first secondary winding further comprises a sixth metal spiral formed at least in part from the second metal layer, wherein the sixth metal spiral extends in the clockwise direction from an eleventh end coupled to the fourth end of the second metal spiral via a second metallized via hole to a twelfth end coupled to the second signal port, wherein the fifth metal spiral is interlaced with the sixth metal spiral; the second primary winding further comprises a seventh metal spiral formed at least in part from the second metal layer, wherein the seventh metal spiral extends in the counterclockwise direction from a thirteenth end coupled to the sixth end of the third metal spiral via a third metallized via hole to a fourteenth end coupled to the second signal ground; and the second secondary winding further comprises an eighth metal spiral formed at least in part from the second metal layer, wherein the eighth metal spiral extends in the counterclockwise direction from a fifteenth end coupled to the eighth end of the fourth metal spiral via a fourth metallized via hole to a sixteenth end coupled to the third signal port, wherein the seventh metal spiral is interlaced with the eighth metal spiral.

Aspect 9: The power splitter of aspect 8, wherein the first metal spiral and the third metal spiral include a common metal segment separating the second metal spiral from the fourth metal spiral.

Aspect 10: The power splitter of aspect 8, wherein: the first signal ground comprises an upper voltage rail; the second signal ground comprises a lower voltage rail; and the third signal ground comprises a capacitor coupled between the fourteenth end of the seventh metal spiral and the lower voltage rail.

Aspect 11: A transformer, comprising: a first primary winding comprising a first metal spiral formed at least in part from a first metal layer, wherein the first metal spiral extends in a first direction from a first end to a second end; and a secondary winding comprising a second metal spiral formed at least in part from the first metal layer, wherein the second metal spiral extends in the first direction from a third end to a fourth end, wherein first metal spiral is interlaced with the second metal spiral.

Aspect 12: The transformer of aspect 11, further comprising: a first metalized via hole coupled to the second end of the first metal spiral; and a second metalized via hole coupled to the fourth end of the second metal spiral.

Aspect 13: The transformer of aspect 12, wherein: the first primary winding comprises a third metal spiral formed at least in part from a second metal layer, wherein the third metal spiral extends in the first direction from the first metalized via hole; and the secondary winding comprises a fourth metal spiral formed at least in part from the second metal layer, wherein the third metal spiral extends in the first direction from the second metalized via hole, wherein third metal spiral is interlaced with the fourth metal spiral.

Aspect 14: The transformer of aspect 13, wherein the first and second spirals are substantially vertically aligned with the third and fourth spirals.

Aspect 15: The transformer of aspect 13 or 14, wherein: the first primary winding comprises a fifth metal spiral formed at least in part from the second metal layer, wherein the fifth metal spiral extends in a second direction from a fifth end of the third metal spiral to a sixth end of the fifth metal spiral, wherein the second direction is opposite the first direction; and the secondary winding comprises a sixth metal spiral formed at least in part from the second metal layer, wherein the sixth metal spiral extends in the second direction from a seventh end of the fourth metal spiral to an eighth end of the sixth metal spiral, wherein fifth metal spiral is interlaced with the sixth metal spiral.

Aspect 16: The transformer of aspect 15, further comprising: a third metalized via hole coupled to the sixth end of the fifth metal spiral; and a fourth metalized via hole coupled to the eighth end of the sixth metal spiral.

Aspect 17: The transformer of aspect 16, wherein: the first primary winding comprises a seventh metal spiral formed at least in part from the first metal layer, wherein the seventh metal spiral extends in the second direction from the third metalized via hole to a ninth end of the seventh metal spiral; and the secondary winding comprises an eighth metal spiral formed at least in part from the first metal layer, wherein the eighth metal spiral extends in the second direction from the fourth metalized via hole to a tenth end of the eighth metal spiral, wherein seventh metal spiral is interlaced with the eighth metal spiral.

Aspect 18: The transformer of aspect 13, further comprising a second primary winding comprising a fifth metal spiral formed at least in part from the second metal layer, wherein the fifth metal spiral extends in a second direction from a fifth end to a sixth end of the fifth metal spiral, wherein the second direction is opposite the first direction; wherein the secondary winding comprises a sixth metal spiral formed at least in part from the second metal layer, wherein the sixth metal spiral extends in the second direction from a seventh end of the fourth metal spiral to an eighth end of the sixth metal spiral, wherein fifth metal spiral is interlaced with the sixth metal spiral.

Aspect 19: The transformer of aspect 18, further comprising: a third metalized via hole coupled to the sixth end of the fifth metal spiral; and a fourth metalized via hole coupled to the eighth end of the sixth metal spiral.

Aspect 20: The transformer of aspect 19, wherein: the second primary winding comprises a seventh metal spiral formed at least in part from the first metal layer, wherein the seventh metal spiral extends in the second direction from the third metalized via hole to a ninth end of the seventh metal spiral; and the secondary winding comprises an eighth metal spiral formed at least in part from the first metal layer, wherein the eighth metal spiral extends in the second direction from the fourth metalized via hole to a tenth end of the eighth metal spiral, wherein seventh metal spiral is interlaced with the eighth metal spiral.

Aspect 21: The transformer of aspect 11, wherein: the first primary winding further comprises a third metal spiral formed at least in part from the first metal layer, wherein the first metal spiral extends in a second direction from a fifth end to a sixth end, the second direction being opposite the first direction, wherein the third metal spiral is situated adjacent to the first metal spiral to form an 8-shaped configuration; and a secondary winding comprising a fourth metal spiral formed at least in part from the first metal layer, wherein the second metal spiral extends in the second direction from a seventh end to an eighth end, wherein third metal spiral is interlaced with the fourth metal spiral, and wherein the fourth metal spiral is situated adjacent to the second metal spiral to form another 8-shaped configuration.

Aspect 22: A transformer, comprising: a primary winding including a first set of one or more cascaded metal spirals; and a secondary winding including a second set of one or more cascaded metal spirals, wherein the first set of one or more cascaded metal spirals are interlaced with the second set of one or more cascaded metal spirals, respectively.

Aspect 23: A method of coupling signals across coupled inductors in accordance with another aspect of the disclosure, comprising routing an input signal via a first metal spiral on a metal layer; and generating an output signal across a second metal spiral, wherein the first metal spiral is interlaced with the second metal spiral on the metal layer.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A power combiner, comprising:
a first signal port configured to receive a first input signal;
a second signal port configured to receive a second input signal;
a third signal port configured to output an output signal with a power level related to a sum of a power level of the first input signal and a power level of the second input signal;
a first transformer, comprising:
a first primary winding comprising a first metal spiral formed at least in part from a first metal layer, wherein the first metal spiral extends in a counterclockwise direction from a first end coupled to the first signal port to a second end coupled directly or indirectly to a first signal ground; and
a first secondary winding comprising a second metal spiral formed at least in part from the first metal layer, wherein the second metal spiral extends in the counterclockwise direction from a third end coupled to a second signal ground to a fourth end coupled directly or indirectly to the third signal port, wherein the first metal spiral is interlaced with the second metal spiral; and
a second transformer, comprising:
a second primary winding comprising a third metal spiral formed at least in part from the first metal layer, wherein the third metal spiral extends in a clockwise direction from a fifth end coupled to the second signal port to a sixth end coupled directly or indirectly to the first signal ground; and
a second secondary winding comprising a fourth metal spiral formed at least in part from the first metal layer, wherein the fourth metal spiral extends in the clockwise direction from a seventh end coupled to the second signal ground to an eighth end coupled directly or indirectly to the third signal port, wherein the third metal spiral is interlaced with the fourth metal spiral.

2. The power combiner of claim 1, wherein at least one of the second metal spiral or the fourth metal spiral each includes a metal segment separating the first metal spiral from the third metal spiral.

3. The power combiner of claim 1, wherein:
the first primary winding further comprises a fifth metal spiral formed at least in part from a second metal layer, wherein the fifth metal spiral extends in the counterclockwise direction from a ninth end coupled to the second end of the first metal spiral via a first metallized via hole to a tenth end coupled to the first signal ground;
the first secondary winding further comprises a sixth metal spiral formed at least in part from the second metal layer, wherein the sixth metal spiral extends in the counterclockwise direction from an eleventh end coupled to the fourth end of the second metal spiral via a second metallized via hole to a twelfth end coupled to the third signal port, wherein the fifth metal spiral is interlaced with the sixth metal spiral;
the second primary winding further comprises a seventh metal spiral formed at least in part from the second metal layer, wherein the seventh metal spiral extends in the clockwise direction from a thirteenth end coupled to the sixth end of the third metal spiral via a third metallized via hole to a fourteenth end coupled to the first signal ground; and
the second secondary winding further comprises an eighth metal spiral formed at least in part from the second metal layer, wherein the eighth metal spiral extends in the clockwise direction from a fifteenth end coupled to the eighth end of the fourth metal spiral via a fourth metallized via hole to a sixteenth end coupled to the third signal port, wherein the seventh metal spiral is interlaced with the eighth metal spiral.

4. The power combiner of claim 3, wherein the sixth metal spiral and the eighth metal spiral include a common metal segment separating the fifth metal spiral from the seventh metal spiral.

5. The power combiner of claim 1, wherein:
the first signal ground comprises an upper voltage rail; and
the second signal ground comprises a lower voltage rail.

6. A power splitter, comprising:
a first signal port configured to receive an input signal;
a second signal port configured to output a first output signal;
a third signal port configured to output a second output signal, wherein a sum of respective power levels of the first and second output signals is related to a power level of the input signal;
a first transformer, comprising:
a first primary winding comprising a first metal spiral formed at least in part from a first metal layer, wherein the first metal spiral extends in a clockwise direction from a first end coupled to the first signal port to a second end coupled directly or indirectly to a first signal ground; and
a first secondary winding comprising a second metal spiral formed at least in part from the first metal layer, wherein the second metal spiral extends in the clockwise direction from a third end coupled to a second signal ground to a fourth end coupled directly or indirectly to the second signal port, wherein the first metal spiral is interlaced with the second metal spiral; and
a second transformer, comprising:
a second primary winding comprising a third metal spiral formed at least in part from the first metal layer, wherein the third metal spiral extends in a counterclockwise direction from a fifth end coupled to the first signal port to a sixth end coupled to a third signal ground; and
a second secondary winding comprising a fourth metal spiral formed at least in part from the first metal layer, wherein the fourth metal spiral extends in the counterclockwise direction from a seventh end coupled to the second signal ground to an eighth end coupled to the third signal port, wherein the third metal spiral is interlaced with the fourth metal spiral.

7. The power splitter of claim 6, wherein at least one of the second metal spiral or the fourth metal spiral each includes a metal segment separating the first metal spiral from the third metal spiral.

8. The power splitter of claim 6, wherein:
the first primary winding further comprises a fifth metal spiral formed at least in part from a second metal layer, wherein the fifth metal spiral extends in the clockwise direction from a ninth end coupled to the second end of the first metal spiral via a first metallized via hole to a tenth end coupled to the first signal ground;
the first secondary winding further comprises a sixth metal spiral formed at least in part from the second metal layer, wherein the sixth metal spiral extends in the clockwise direction from an eleventh end coupled to the fourth end of the second metal spiral via a second metallized via hole to a twelfth end coupled to the second signal port, wherein the fifth metal spiral is interlaced with the sixth metal spiral;
the second primary winding further comprises a seventh metal spiral formed at least in part from the second metal layer, wherein the seventh metal spiral extends in the counterclockwise direction from a thirteenth end coupled to the sixth end of the third metal spiral via a third metallized via hole to a fourteenth end coupled to the third signal ground; and
the second secondary winding further comprises an eighth metal spiral formed at least in part from the second metal layer, wherein the eighth metal spiral extends in the counterclockwise direction from a fifteenth end coupled to the eighth end of the fourth metal spiral via a fourth metallized via hole to a sixteenth end coupled to the third signal port, wherein the seventh metal spiral is interlaced with the eighth metal spiral.

9. The power splitter of claim 8, wherein the first metal spiral and the third metal spiral include a common metal segment separating the second metal spiral from the fourth metal spiral.

10. The power splitter of claim 8, wherein:
the first signal ground comprises an upper voltage rail;
the second signal ground comprises a lower voltage rail; and
the third signal ground comprises a capacitor coupled between the fourteenth end of the seventh metal spiral and the lower voltage rail.

11. A transformer, comprising:
a first primary winding comprising a first metal spiral formed at least in part from a first metal layer, wherein the first metal spiral extends in a first direction from a first end to a second end; and
a secondary winding comprising a second metal spiral formed at least in part from the first metal layer, wherein the second metal spiral extends in the first direction from a third end to a fourth end, wherein first metal spiral is interlaced with the second metal spiral.

12. The transformer of claim 11, further comprising:
a first metalized via hole coupled to the second end of the first metal spiral; and
a second metalized via hole coupled to the fourth end of the second metal spiral.

13. The transformer of claim 12, wherein:
the first primary winding comprises a third metal spiral formed at least in part from a second metal layer, wherein the third metal spiral extends in the first direction from the first metalized via hole; and
the secondary winding comprises a fourth metal spiral formed at least in part from the second metal layer, wherein the third metal spiral extends in the first direction from the second metalized via hole, wherein third metal spiral is interlaced with the fourth metal spiral.

14. The transformer of claim 13, wherein the first and second spirals are substantially vertically aligned with the third and fourth spirals.

15. The transformer of claim 13, wherein:
the first primary winding comprises a fifth metal spiral formed at least in part from the second metal layer, wherein the fifth metal spiral extends in a second direction from a fifth end of the third metal spiral to a sixth end of the fifth metal spiral, wherein the second direction is opposite the first direction; and
the secondary winding comprises a sixth metal spiral formed at least in part from the second metal layer, wherein the sixth metal spiral extends in the second direction from a seventh end of the fourth metal spiral to an eighth end of the sixth metal spiral, wherein fifth metal spiral is interlaced with the sixth metal spiral.

16. The transformer of claim 15, further comprising:
a third metalized via hole coupled to the sixth end of the fifth metal spiral; and
a fourth metalized via hole coupled to the eighth end of the sixth metal spiral.

17. The transformer of claim 16, wherein:
the first primary winding comprises a seventh metal spiral formed at least in part from the first metal layer, wherein the seventh metal spiral extends in the second direction from the third metalized via hole to a ninth end of the seventh metal spiral; and
the secondary winding comprises an eighth metal spiral formed at least in part from the first metal layer, wherein the eighth metal spiral extends in the second direction from the fourth metalized via hole to a tenth end of the eighth metal spiral, wherein seventh metal spiral is interlaced with the eighth metal spiral.

18. The transformer of claim 13, further comprising a second primary winding comprising a fifth metal spiral formed at least in part from the second metal layer, wherein the fifth metal spiral extends in a second direction from a fifth end to a sixth end of the fifth metal spiral, wherein the second direction is opposite the first direction:
wherein the secondary winding comprises a sixth metal spiral formed at least in part from the second metal layer, wherein the sixth metal spiral extends in the second direction from a seventh end of the fourth metal spiral to an eighth end of the sixth metal spiral, wherein fifth metal spiral is interlaced with the sixth metal spiral.

19. The transformer of claim 18, further comprising:
a third metalized via hole coupled to the sixth end of the fifth metal spiral; and
a fourth metalized via hole coupled to the eighth end of the sixth metal spiral.

20. The transformer of claim 11, wherein:
the first primary winding further comprises a third metal spiral formed at least in part from the first metal layer, wherein the first metal spiral extends in a second direction from a fifth end to a sixth end, the second direction being opposite the first direction, wherein the third metal spiral is situated adjacent to the first metal spiral to form an 8-shaped configuration; and
a secondary winding comprising a fourth metal spiral formed at least in part from the first metal layer, wherein the second metal spiral extends in the second direction from a seventh end to an eighth end, wherein third metal spiral is interlaced with the fourth metal spiral, and wherein the fourth metal spiral is situated adjacent to the second metal spiral to form another 8-shaped configuration.
